(19) United States
(12) Patent Application Publication
(10) Pub. No.: US 2005/0077071 A1
(43) Pub. Date: Apr. 14, 2005

(54) Electrical outlet covers

(76) Inventor: Brian D. Bangert, Covina, CA (US)

Correspondence Address: JOSEPH E. MUETH, ESQ.;JOSEPH E. MUETH LAW CORPORATION, 8TH FLOOR, 225 SOUTH LAKE AVE., PASADENA, CA, 91101, US

(21) Appl. No.: 10/682,163

(22) Filed: Oct. 8, 2003

(51) Int. Cl. H05K 5/03

(52) U.S. Cl. 174/66

(57) ABSTRACT

A building surface having therein at least one electrical outlet having thereover an outlet cover. The outlet cover has an inner surface facing the electrical outlet and an opposed exposed outer surface. The exposed outer exposed surface has an esthetically pleasing surface finish or treatment and the adjacent building surface has a matching or complementary exposed outer surface finish or treatment so as to make the appearance of the outer exposed surface of the outlet cover blend with the appearance of the building surface.

### FIELD OF INVENTION

This invention relates to electrical outlet covers.

### BACKGROUND OF INVENTION

The modern home or office contains numerous electrical outlets. The modern home or office is also often the subject of great care and expensive in regard t interior finishing and decoration. The increasing desire for esthetic enhancement of the appearance of buildings must also accommodate the needs of modern technology which require the incorporation of even more electrical outlets in walls and base boards. In their ordinary forms, electrical outlets are seen as unsightly and as detracting form the desired appearance of a room or office. Any esthetic effects must also accommodate the need for easy access to the outlet itself.

In another aspect, exposed electrical outlets present a hazard to young curious children who, oblivious of the danger, may stick their small fingers into the outlet.

The present invention addresses the desire for improved esthetics while accommodating the needs of modern technology.

The present invention at the same time affords safeguards for small children.

### SUMMARY OF THE INVENTION

Briefly, this invention comprises a building surface having therein at least one electrical outlet having thereover an outlet cover, said outlet cover having an inner surface facing the electrical outlet and an opposed exposed outer surface, said exposed outer exposed surface having an esthetically pleasing surface finish or treatment, the adjacent building surface having matching or complementary exposed outer surface finish or treatment so as to make the appearance of the outer exposed surface of the outlet cover blend with the appearance of the building surface.

In one preferred embodiment, the inner surface of the outlet cover has non- conductive prongs which plug into the electrical outlet and hold the cover in place.

In another embodiment, which is especially child resistant, the outlet cover is slidably received and held in spaced apart channels at the side margins of the electrical outlet.

### DESCRIPTION OF THE DRAWINGS

Turning to the drawings:

FIG. 1 is a perspective view of a standard wall outlet in a tiled or simulated tile wall surface showing the embodiment of this invention wherein the inner surface of the outlet cover is provided with non-electrically conductive prongs adapted to be plugged into the outlet to hold the outlet cover in place and the outer surface of the outlet cover has a tiled surface to match the wall surface.

FIG. 2 is a plan view showing the outlet cover of FIG. 1 actually plugged into the wall outlet.

FIG. 3 is a perspective view of the wall outlet and cover showing the prongs in dotted lines.

FIGS. 4, 5 and 6 showing the outlet cover with prongs in plan, said and top views, respectively.

FIG. 7 is a perspective view of an alternate embodiment of the invention wherein the outlet cover is held in place by spaced apart channels, one at each side of the wall outlet, with the channels forming part of the screw-held wall plate, with the outlet cover slidably received in said channels.

FIG. 8 is a top view of the embodiment of FIG. 7 with the sliding element fully inserted.

FIG. 9 is a side view of the embodiment of FIG. 7 with the sliding element substantially, slidably withdrawn.

FIG. 10 is a front view of the embodiment of FIG. 7.

FIG. 11 is a front view of the embodiment of FIG. 7 with the slide element fully slid into place.

FIG. 12 shows a tiled wall containing various wall outlets essentially flush mounted in the wall.

FIG. 13 shows how the view of FIG. 12 looks with the wall plate covers in place.

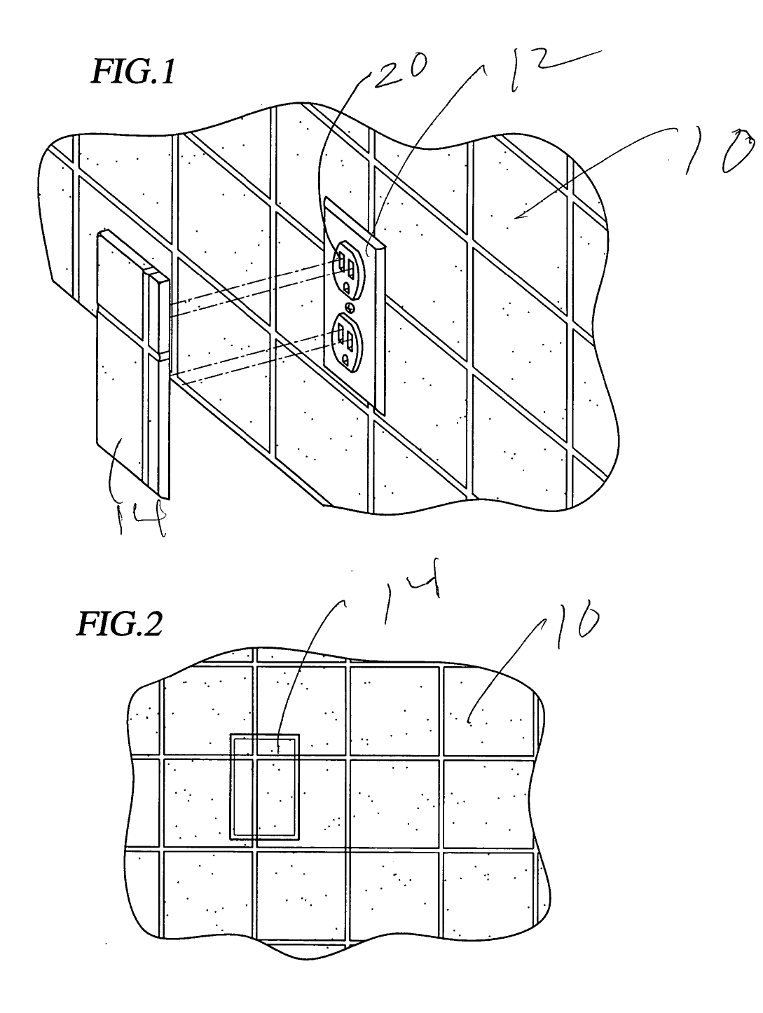

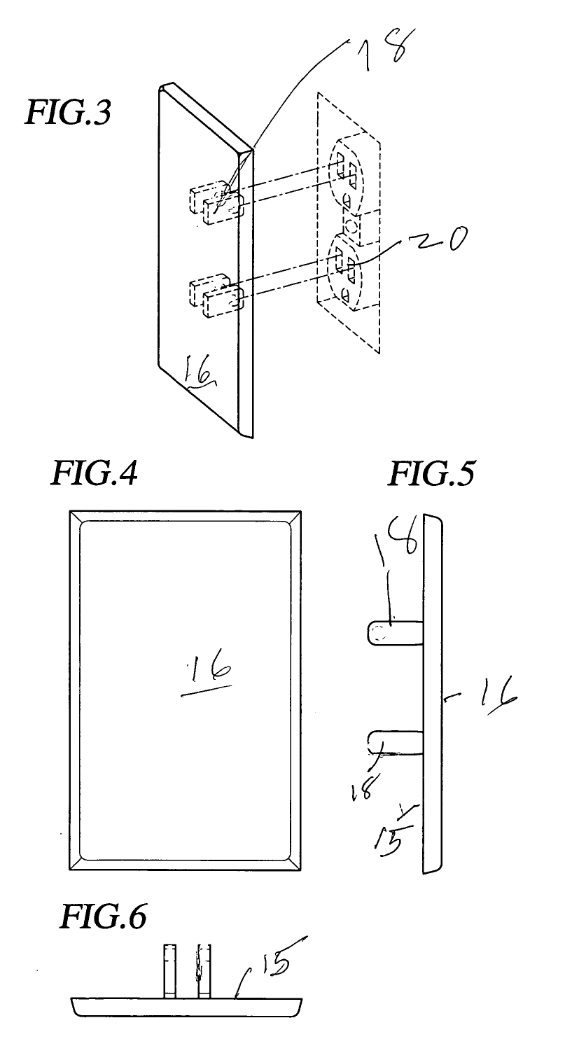

### DESCRIPTION OF THE PREFERRED EMBODIMENTS

Turning to the drawings in more detail, the planar wall surface 10 is shown with a standard electrical outlet 12 generally flush mounted therein. The outlet cover 14 has an inner surface 15 which faces the outlet 12 and an exposed outer surface 16. The inner surface 15 carries a pair of electrically non-conductive prongs 18 which plug into the standard openings 20 in the outlet 12 and hold the outlet cover 14 in place, snugly against the outlet 12.

The outer surface 16 is provided with any type of finish or surface. This finish may be painted, printed, or wall papered. The finish may be smooth, rough or textured; solid or decorated by virtually any desired form of artwork.

The planar wall surface 10 has an identical or complementary finish or surface. In this way, when the outlet cover 14 is held in place by the prongs 18, the appearance of the outer surface 16 of the outlet cover 14 blends with the appearance of the wall surface 10 to provide a pleasing esthetic effect. The outlet is made less prominent to the eye.

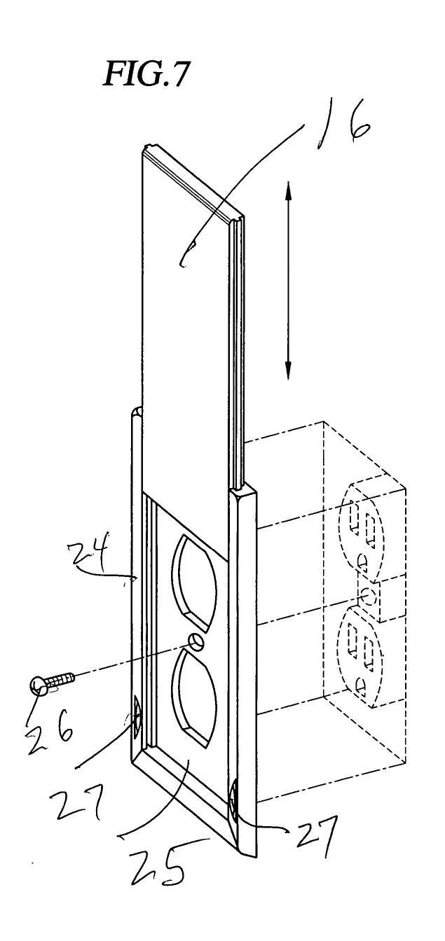

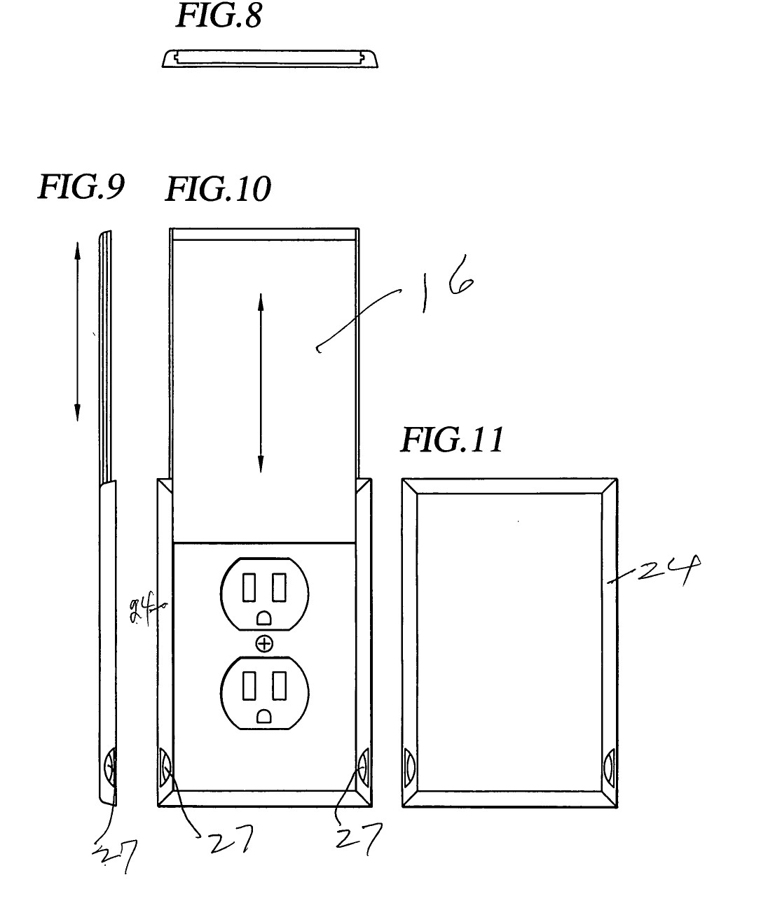

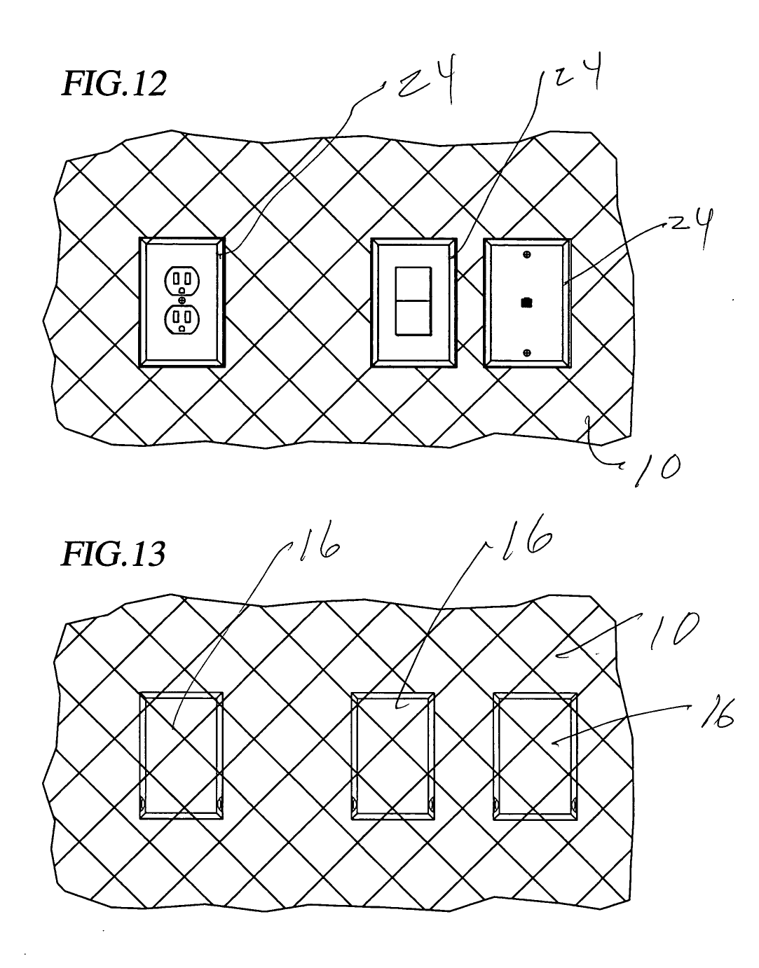

The embodiment of FIGS. 7 to 13 is likewise used in a wall or similar structure. In this embodiment, the outlet cover 22 is slidably received and held in spaced apart channels 24 in a tongue-and-groove manner, the channels forming part of the wall plate 25. The wall plate is attached to the electrical outlet by screw 26.

Preferably, the channels are provided with small flexible projections 27 which are receivable in small indentations in the side margins, located near one end, of the outlet cover 22. When the outlet cover 22 is slid all the way down as in FIG. 3, the projections snap into the indentations and help to prevent a child from sliding or moving the outlet cover, thereby making the outlet itself safely inaccessible to a small child. When it is desired to use the outlet, the projections 27 are manually depressed which forces them out of the indentations, allowing the outlet cover to be slid upwardly in channels 24.

1. A building surface having therein at least one electrical outlet having thereover an outlet cover, said outlet cover having an inner surface facing the electrical outlet and an opposed exposed outer surface, said exposed outer exposed surface having an esthetically pleasing surface finish or treatment, the adjacent building surface having matching or complementary exposed outer surface finish or treatment so as to make the appearance of the outer exposed surface of the outlet cover blend with the appearance of the building surface.

2. The building surface of claim 1 wherein the inner surface of the outlet cover has non-conductive prongs which plug into the electrical outlet and hold the cover in place.

3. The building surface of claim 1 wherein the outlet cover is slidably received and held in spaced apart channels at the side margins of the electrical outlet.
